(19) United States
(12) Patent Application Publication
(10) Pub. No.: US 2003/0030099 A1
(43) Pub. Date: Feb. 13, 2003

(54) Flash memory structure

(76) Inventors: Jung-Yu Hsieh, Taipei Hsien (TW); Chin-Hsiang Lin, Nantou Hsien (TW)

Correspondence Address: J.C. Patents, Inc., 4 Venture, Suite 250, Irvine, CA, 92618, US

(21) Appl. No.: 09/990,397

(22) Filed: Nov. 20, 2001

(30) Foreign Application Priority Data
May 4, 2001 (TW) 90110699

(51) Int. Cl. H01L 29/788

(52) U.S. Cl. 257/315

(57) ABSTRACT

A flash memory structure which includes a tunneling oxide layer, a floating gate, a dielectric stacked layer, a control gate and a source/drain region. The dielectric stacked layer is formed by successively stacking a first oxide layer, a dielectric layer made of a high dielectric constant material and a second oxide layer, and is installed between the floating gate and the control gate. The floating gate is formed on the tunneling oxide layer. The control gate is formed on the dielectric stacked layer. The source/drain region is installed within the substrate on the two sides of the floating gate.

### CROSS-REFERENCE TO RELATED APPLICATION

This application claims the priority benefit of Taiwan application serial no. 90110699, filed May 4, 2001.

### BACKGROUND OF THE INVENTION

1. Field of the Invention

The present invention relates to a memory structure. More particularly, the present invention relates to a flash memory structure.

2. Description of the Related Art

Due to the recent demand of portable electronic products, the demand for flash memory has noticeably increased. Since its manufacturing technique has been well developed, the cost is greatly reduced. This development is not only exciting desires for consumers but also providing a new market application. It has been that the erasable and programmable ROM recently designed with flash memory structures has already had greatly faster access speed. The memory card of a digital camera, the memory of a personal electronic notebook, personal MP3 walkman, electronic answering machine and a programmable IC are all part of the market for flash memory applications.

FIG. 1 is a diagram in cross-sectional view of a flash memory structure in the related art. Referring to FIG. 1, the structure includes a tunneling oxide layer 102, a control gate 108, an oxide layer 110, a floating gate 104 and a source/drain region 106. The floating gate 104 is formed on the tunneling layer 102. The oxide layer 110 is formed on the floating gate 104. The control gate 108 is formed on the oxide layer 110. The source/drain region 106 is formed in the substrate 100 on the two sides of the floating gate 104.

During programming of the flash memory, a suitable programming voltage is respectively applied to the source/drain region 106 and control gate 108. The electrons flow through the channel from the source region 106 to the drain region 106′. During this process, a portion of the electrons passes through the tunneling oxide layer 102 below the polysilicon floating gate 104. The electrons enter and distribute evenly throughout the entire floating gate 104. The phenomenon that the electrons pass through the tunneling oxide layer 102 and enter the floating gate 104 is called tunneling effect.

Two types of tunneling effects can occur. One effect is called Channel Hot-Electron Injection and the other effect is called Fowler-Nordheim (F-N) Tunneling. The flash memory usually uses the mechanism of hot-electron injection for writing and uses the mechanism of F-N tunneling for erasing. However, if weak points exist in the tunneling oxide layer below the floating gate, then current leakage of the device can easily occur and affecting the reliability of the device.

### SUMMARY OF THE INVENTION

In order to resolve the problem of leakage in the flash memory device, the present method uses a stacked structure formed by an oxide-nitride-oxide (ONO) stacked layer as a dielectric layer between the floating gate and the control gate.

Since the silicon nitride layer of the ONO dielectric layer has the effect of keeping electric charges, the electrons injected into the ONO layer are not evenly distributed within the entire silicon nitride layer. By contrast, the electrons locally concentrated on the silicon nitride by a concentration distribution of Gaussian distribution. Thus, the silicon oxide layer is rather insensitive to its defects and device current leakage does not easily occur.

Moreover, there are still many advantages for an ONO dielectric layer. During device programming, the electrons are only locally stored in the channel above the adjacent source region or drain region. Hence, during programming, the voltage can be respectively exerted onto the source/drain region and gate. Electrons are locally distributed in the silicon nitride by the Gaussian distribution, adjacent the source/drain region. By changing the applied voltage of the gate and the source/drain region on the two sides of the gate, the ONO dielectric layer may have two or one electron concentrations with Gaussian distribution, or even no electrons. Thus, the flash memory that uses silicon nitride material as a dielectric layer can be written in four states within a single memory cell to serve as a 1 cell 2 bit flash memory.

However, during programming of the above-described flash memory, a suitable voltage must be applied onto the source/drain region and the control gate. The voltage value required during this procedure varies according to the material of the dielectric material between the floating gate and the control gate. Hence, finding a way to reduce the voltage value to a minimum is an essential issue.

### SUMMARY OF THE INVENTION

The present invention provides a flash memory structure, wherein the voltage value required in operating the flash memory is reduced and energy consumption is decreased.

As embodied and broadly described herein, the invention provides a flash memory structure which includes a tunneling oxide layer, a floating gate, a dielectric stacked layer, a control gate and a source/drain region. The dielectric stacked layer is formed by successively stacking a first oxide layer, a dielectric layer with a high dielectric constant material and a second oxide layer, and is located between the floating gate and the control gate. The floating gate is formed on the tunneling oxide layer. The control gate is formed on the dielectric stacked layer. The source/drain region is formed in the substrate on the two sides of the floating gate. Moreover, whether or not to omit the second oxide layer between the high dielectric constant dielectric layer and the control gate is optionally decided according to the band gap size of the high dielectric constant dielectric layer. If the band gap of the utilized high dielectric constant dielectric layer is as wide or wider than the silicon oxide band gap, then the second oxide layer is omitted. Alternately, if the band gap of the high dielectric constant dielectric layer is less than the silicon oxide band gap, then the second silicon oxide layer must also be included. High dielectric constant used in the invention is a term that refers to a dielectric constant material that is greater than the dielectric constant of Si₃N₄/SiO₂ (NO). Band gap refers to a gap between two energy bands existing between metal and semiconductor. Further still, since the aluminum oxide has properties of high dielectric constant and high energy gap, as the aluminum oxide is used as the dielectric layer, there is no need of additional dielectric layer.

Since the present invention uses a high electric constant dielectric layer as a the material for a dielectric stacked layer, thus, the required voltage that is applied for operating a flash memory is reduced and energy consumption is decreased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention, and, together with the description, serve to explain the principles of the invention. In the drawings,

FIG. 1 is a drawing in cross-sectional view of a flash memory structure in the related art; and

FIG. 2 is a drawing in cross-sectional view of a flash memory structure according to one preferred embodiment of this invention.

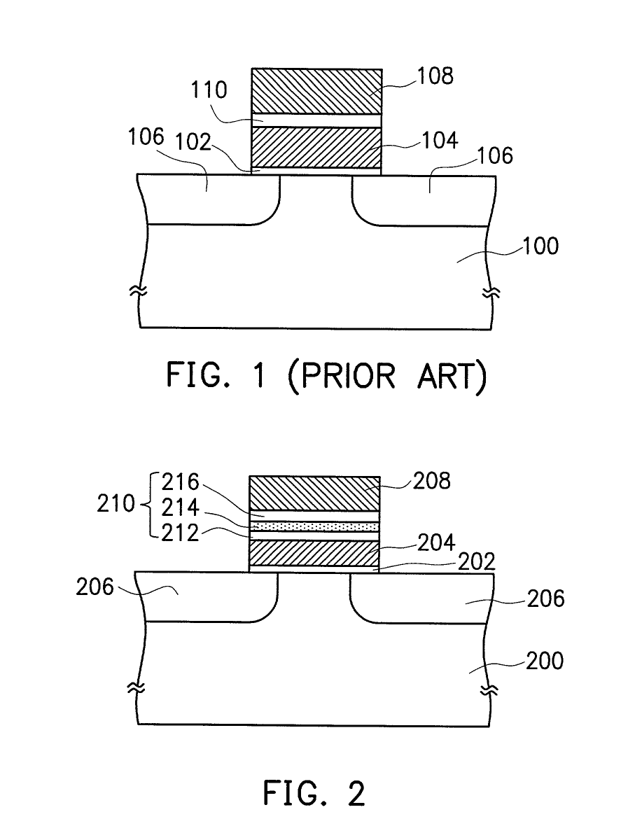

### DESCRIPTION OF THE PREFERRED EMBODIMENTS

FIG. 2 is a drawing in cross-sectional view of a flash memory structure according to one preferred embodiment of this invention. Referring to FIG. 2, the structure includes a tunneling oxide layer 202, a control gate 208, a floating gate 204, a dielectric stacked layer 210 and a source/drain region 206. The components are placed in relation such that the floating gate 204 is located upon the tunneling oxide layer 202. The dielectric stacked layer 210 is formed on the floating gate 204. The control gate 208 is formed on the dielectric stacked layer 210. The source/drain region 206 is formed in the substrate 200 on the two sides of the floating gate 204. The dielectric stacked layer 210 is formed from successively stacking a first oxide layer 212, a dielectric layer 214 and a second oxide layer 216. The dielectric layer 214 is made of a material with a high dielectric constant.

The material of the dielectric layer 214 within the dielectric stacked layer 210 has a high dielectric constant (∈) for any requirements. Thus, the applied voltage required during operation of the flash memory is reduced and energy consumption is decreased. The reason is that during operation of the flash memory, the voltage applied to the control gate is indicated by VTCs in the equation (1) below:

$${V}_{TCS} = \frac{1}{GCR} \times {V}_{TFS} - \frac{q}{{C}_{C}} \qquad ( 1 )$$

In equation (1), GCR represents Gate Coupling Ratio, which value is indicated in the equation (2) below:

$$GCR = \frac{{C}_{C}}{{C}_{T}} = \frac{{C}_{ONO}}{{C}_{Tox} + {C}_{ONO}} \qquad ( 2 )$$

In equation (2), Cₜₒₓ represents capacitance of tunneling oxide layer, and C_{ONO} represents capacitance of the ONO layer.

Therefore, as shown in the above equations (1) and (2), if the applied voltage V_{TCS} desired to be reduced, then the GCR value must be increased. In order to increase the GCR value, the capacitance value of the tunneling oxide capacitance must be increased. The relationship equation between the capacitance and the dielectric constant (represented by ∈) is indicated in the equation (3) below:

$$C = ϵ \times \frac{A}{d} \qquad ( 3 )$$

Hence, in summarizing equations (1), (2) and (3), in order to reduce the applied voltage V_{TCS}, the dielectric constant of the dielectric layer 214 within the dielectric stacked layer 210 must be increased. The applied voltage required during operation of the flash memory is thereby reduced and energy consumption is decreased.

The first oxide layer 212 within the dielectric stacked layer 210 is used to enhance the adhering ability between the floating gate 204 and the high dielectric constant dielectric layer 214, as well as to minimize the occurrence of defects. The second oxide layer 216 within the dielectric stacked layer 210 is used to enhance the adhering ability between the high dielectric constant dielectric layer 214 and the above control gate 208, as well as to minimize the occurrence of defects.

High dielectric constant material is a term that refers to a dielectric constant material that is greater than a Si₃N₄/SiO₂ (NO) dielectric constant material. High dielectric constant layer 214 is made of a material, such as Al₂O₃, Y₂O₃, ZrSiₓO_{y}, HfSiₓO_{y}, La₂O₃, ZrO₂, HfO₂, Ta₂O₅, Pr₂O₃ or TiO₂. Table 1 below indicates the dielectric constants in the above-described dielectric layer, which furthermore includes the dielectric constants Si₃N₄/SiO₂, SiO₂ and Si₃N₄.

TABLE 1

| Materials | Dielectric Constant |
|---|---|
| SiO₂ | 2.9 |
| Si₃N₄ | 7.5 |
| NO (Si₃N₄/SiO₂) | 7˜8 |
| Al₂O₃ | 10 |
| Y₂O₃ | 12˜14 |
| ZrSiₓO_{y} | 12˜22 |
| HfSiₓO_{y} | 15˜25 |
| La₂O₃ | 20 |
| ZrO₂ | 22 |
| HfO₂ | 25 |
| Ta₂O₅ | 26 |
| Pr₂O₃ | 31 |
| TiO₂ | 80 |

As indicated in Table 1, the dielectric constant of the high dielectric constant materials is usually greater than the Si₃N₄/SiO₂ dielectric constant value of 8. The high dielectric constant dielectric layer 214 in the present embodiment can also be an admixture of the above-mentioned high dielectric constant materials or a stacked layer of the above-mentioned high dielectric constant materials.

Moreover, whether or not to leave out the second oxide layer 216 between the high dielectric constant dielectric layer 214 and the control gate 208 within the dielectric stacked layer 210 is decided according to the band gap size of the high dielectric constant dielectric layer 214 used. If the band gap of the utilized high dielectric constant dielectric layer 214 is as wide or is wider than the silicon oxide band gap, then the second oxide layer 216 is left out. Alternately, if the band gap of the high dielectric constant dielectric layer 214 is less than he silicon oxide band gap, then the second oxide layer 216 is included. Table 2 below indicates the band gap values of the utilized dielectric layer 214 material in the present embodiment and furthermore includes the band gap values of SiO₂ and Si₃N₄.

TABLE 2

| Material | Bang Gap (eV) |
|---|---|
| SiO₂ | 9 |
| Si₃N₄ | 5.3 |
| Al₂O₃ | 8.0 |
| Y₂O₃ | 5.6 |
| ZrSiₓO_{y} | 6.5 |
| HfSiₓO_{y} | 6.5 |
| La₂O₃ | 4 |
| ZrO₂ | 7.8 |
| HfO₂ | 6 |
| Ta₂O₅ | 4.4 |
| Pr₂O₃ | — |
| TiO₂ | 2.3 |

If the band gap of the high dielectric constant dielectric layer 214 is as large or is larger than the silicon oxide layer in the related art, then the high dielectric constant dielectric layer 214 replaces the second oxide layer 216 formed on the high dielectric constant dielectric layer 214 in the related art, and is likewise effective.

As shown in Tables 1 and 2, the Al₂O₃ band gap is greater than the SI₃/N₄ band gap. Since the Al₂O₃ band gap is similar to the SiO₂ band gap, when using Al₂O₃ as the material of the dielectric layer 214, the other oxide layers 212 and 216 within the dielectric stacked layer 210 are replaced, thereby simplifying the manufacturing process of the flash memory.

In summary, the present invention uses a high dielectric constant dielectric layer as the main material between the control gate and the floating gate. Thus, the gate coupling ratio is increased, thereby decreasing the applied voltage required during operation of the flash memory and minimizing energy consumption. If Al₂O₃ is used as the dielectric layer material, the gate coupling ratio is increased, the first and second oxide layers are completely replaced, thereby simplifying the manufacturing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flash memory structure, comprising:
a tunneling oxide layer located upon a substrate;
a floating gate located upon the tunneling oxide layer;
a first oxide layer located upon the floating gate;
a high dielectric constant dielectric layer located upon the first oxide layer;
a second oxide layer, located upon the high dielectric constant dielectric layer, wherein, together with the first oxide layer and the high dielectric constant dielectric layer, a dielectric stacked layer is formed;
a control gate formed on the second oxide layer of the dielectric stacked layer; and
a source/drain region located in the substrate on the two sides of the floating gate.

2. The flash memory structure as defined in claim 1, wherein a band gap value of the high dielectric constant dielectric layer is less than a band gap value of silicon oxide.

3. The flash memory structure as defined in claim 1, wherein a dielectric constant of the high dielectric constant dielectric layer is greater than 8.

4. The flash memory structure as defined in claim 1, wherein the high dielectric constant dielectric layer is a single layer including one material selected from the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

5. The flash memory structure as defined in claim 1, wherein the high dielectric constant dielectric layer is a layer including a mixed material any one selected from the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

6. The flash memory structure as defined in claim 1, wherein the material of the high dielectric constant dielectric layer is stacked layer, each layer of the stacked layer including one selected from the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

7. A flash memory structure, comprising:
a tunneling oxide layer located upon a substrate;
a floating gate located upon the tunneling oxide layer;
a first oxide layer located upon the floating gate;
a high dielectric constant dielectric layer located upon the first oxide layer, wherein, together with the oxide layer, a dielectric stacked layer is formed;
a control gate formed on the high dielectric constant dielectric layer of the dielectric stacked layer; and
a source/drain region located within the substrate on the two sides of the floating gate.

8. The flash memory structure as defined in claim 7, wherein a band gap value of the high dielectric constant dielectric layer is greater than a band gap of silicon oxide.

9. The flash memory structure as defined in claim 7, wherein a band gap value of the high dielectric constant dielectric layer is equivalent to a band gap of silicon oxide.

10. The flash memory structure as defined in claim 7, wherein the high dielectric constant dielectric layer is a single layer including one material selected from the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

11. The flash memory structure as defined in claim 7, wherein the high dielectric constant dielectric layer includes a mixed material selected from any one of the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

12. The flash memory structure as defined in claim 7, wherein the high dielectric constant dielectric layer is a stacked layer, each layer of the stacked layer including one selected from the group consisting of Al₂O₃, Y₂O₃, ZrSiₓO_{y}, HfSiₓO_{y}, La₂O₃, ZrO₂, HfO₂, Ta₂O₅, Pr₂O₃ and TiO₂.

13. A flash memory structure, comprising:
a tunneling oxide layer located upon a substrate;
a floating gate located upon the tunneling oxide layer;
an Al₂O₃ layer located upon the floating gate;
a control gate located upon the Al₂O₃ layer; and
a source/drain region located within the substrate on the two sides of the floating gate.
